(19) United States
(12) Patent Application Publication
(10) Pub. No.: US 2020/0399759 A1
(43) Pub. Date: Dec. 24, 2020

(54) SUBSTRATE PROCESSING APPARATUS, METHOD OF MANUFACTURING SEMICONDUCTOR DEVICE, AND RECORDING MEDIUM

(71) Applicant: KOKUSAI ELECTRIC CORPORATION, Tokyo (JP)

(72) Inventors: Kazuhiko YAMAZAKI, Toyama-shi (JP); Takashi YAHATA, Toyama-shi (JP); Daisuke HARA, Toyama-shi (JP); Kenji SHINOZAKI, Toyama-shi (JP)

(73) Assignee: KOKUSAI ELECTRIC CORPORATION, Tokyo (JP)

(21) Appl. No.: 17/014,420

(22) Filed: Sep. 8, 2020

Related U.S. Application Data
(63) Continuation of application No. PCT/JP2019/009121, filed on Mar. 7, 2019.

(30) Foreign Application Priority Data
Mar. 22, 2018 (JP) 2018-054103

(51) Int. Cl. C23C 16/52; C23C 16/46; C23C 16/44; C23C 16/455; H01L 21/02

(52) U.S. Cl. CPC C23C 16/52; C23C 16/46; H01L 21/02104; C23C 16/45557; C23C 16/4412

(57) ABSTRACT

There is provided a technique that includes: process chamber processing substrate; gas supply system supplying precursor gas into the process chamber; exhaust pipe connected to vacuum pump and evacuating inside of the process chamber; gas concentration sensor configured to measure concentration of the precursor gas passing through the exhaust pipe at front stage of the vacuum pump; a pressure sensor measuring pressure in the exhaust pipe at rear stage of the vacuum pump; dilution gas supply system supplying dilution gas into the vacuum pump or the exhaust pipe at the front stage; and a controller controlling the dilution gas supply system to supply the dilution gas into the vacuum pump or the exhaust pipe at the front stage at low rate corresponding to the measured concentration of the precursor gas and the measured pressure in the exhaust pipe at the rear stage.

### CROSS-REFERENCE TO RELATED APPLICATION

This application is a Bypass Continuation Application of PCT International Application No. PCT/JP2019/009121, filed Mar. 7, 2019, the disclosure of which is incorporated herein in its entirety by reference.

### TECHNICAL FIELD

The present disclosure relates to a substrate processing apparatus, a method of manufacturing a semiconductor device, and a recording medium.

### BACKGROUND

In the related art, as a process of manufacturing a semiconductor device, there has been performed a substrate processing process in which a substrate is loaded into a process chamber of a substrate processing apparatus, a precursor gas or a reaction gas supplied into the process chamber is activated by using plasma, and various thin films such as an insulating film, a semiconductor film or a conductor film are formed on the substrate or removed from the substrate. Plasma is used to promote a reaction for forming a thin film, remove impurities from a thin film, or assist a chemical reaction of a film-forming precursor. In this type of substrate processing apparatus, there has been proposed a technique that prevents an exhaust gas from being combusted on an outlet side of a vacuum pump.

In a case where a gas concentration meter that measures a concentration of a combustible gas is installed in a rear stage of a vacuum pump, there is a problem that when concentration of the combustible gas rises sharply, a dilution gas cannot be supplied in time, whereby the concentration of the combustible gas may become high in the rear stage of the vacuum pump and possibly reach a lower limit of the concentration at which the combustible gas may combusted.

### SUMMARY

Some embodiments of the present disclosure provide a technique capable of reliably suppressing combustion of a combustible gas in a rear stage of a vacuum pump.

Other features will be apparent from description of the present specification and accompanying drawings.

According to one embodiment of the present disclosure, there is provided a technique that includes: a process chamber configured to process a substrate; a gas supply system configured to supply a precursor gas into the process chamber; an exhaust pipe connected to a vacuum pump and configured to evacuate an inside of the process chamber; a gas concentration sensor configured to measure a concentration of the precursor gas passing through a first portion of the exhaust pipe in a front stage of the vacuum pump; a pressure sensor configured to measure a pressure in a second portion of the exhaust pipe in a rear stage of the vacuum pump; a dilution gas supply system configured to supply a dilution gas into the vacuum pump or the first portion of the exhaust pipe in the front stage of the vacuum pump; and a controller configured to be capable of controlling the dilution gas supply system to supply the dilution gas into the vacuum pump or the first portion of the exhaust pipe in the front stage of the vacuum pump at a flow rate corresponding to the measured concentration of the precursor gas and the measured pressure in the second portion of the exhaust pipe in the rear stage of the vacuum pump.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a vertical process furnace of a substrate processing apparatus suitably used in embodiments of the present disclosure, in which the process furnace is shown in a vertical cross-sectional view.

FIG. 2 is a schematic configuration diagram of the vertical process furnace of the substrate processing apparatus suitably used in the embodiments of the present disclosure, in which the process furnace is shown in a cross-sectional view taken along line A-A in FIG. 1.

FIG. 3A is an enlarged horizontal cross-sectional diagram to explain a buffer structure of a substrate processing apparatus suitably used in the embodiments of the present disclosure.

FIG. 3B is a schematic diagram to explain a buffer structure of a substrate processing apparatus suitably used in the embodiments of the present disclosure.

FIG. 4 is a schematic configuration diagram of a controller of a substrate processing apparatus suitably used in the embodiments of the present disclosure, in which a control system of the controller is shown in a block diagram.

FIG. 5 is a flowchart of a substrate processing process according to the embodiments of the present disclosure.

FIG. 6 is a diagram showing gas supply timings in a substrate processing process according to the embodiments of the present disclosure.

FIG. 7A is a diagram showing a flow at the time of setting an initial value in a dilution controller suitably used in the embodiments of the present disclosure.

FIG. 7B is a diagram illustrating an example of calculating initial setting data in a dilution controller suitably used in the embodiments of the present disclosure.

FIG. 8A is a diagram showing a control flow at the time of operating a dilution controller suitably used in the embodiments of the present disclosure.

FIG. 8B is a diagram illustrating an example of calculating an inflow amount of a dilution gas at the time of operating a dilution controller suitably used in the embodiments of the present disclosure.

FIG. 9 is a schematic configuration diagram of a vertical process furnace of a substrate processing apparatus suitably used in a modification of the embodiments of the present disclosure, in which s process furnace is shown in a vertical cross-sectional view.

FIG. 10 is a diagram showing a flow at the time of setting an initial value suitably used in a modification of the embodiments of the present disclosure.

FIG. 11A is a diagram showing a control flow at the time of operating a dilution controller suitably used in a modification of the embodiments of the present disclosure.

FIG. 11B is a diagram illustrating an example of calculating an inflow amount of a dilution gas at the time of operating a dilution controller suitably used in a modification of the embodiments of the present disclosure.

FIG. 12 is a schematic configuration diagram of a vertical process furnace of a substrate processing apparatus suitably used in embodiments of the present disclosure, in which a process furnace is shown in a vertical cross-sectional view.

### DETAILED DESCRIPTION

Reference will now be made in detail to various embodiments, examples of which are illustrated in the accompanying drawings. In the following detailed description, numerous specific details are set forth to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Embodiments of the Present Disclosure

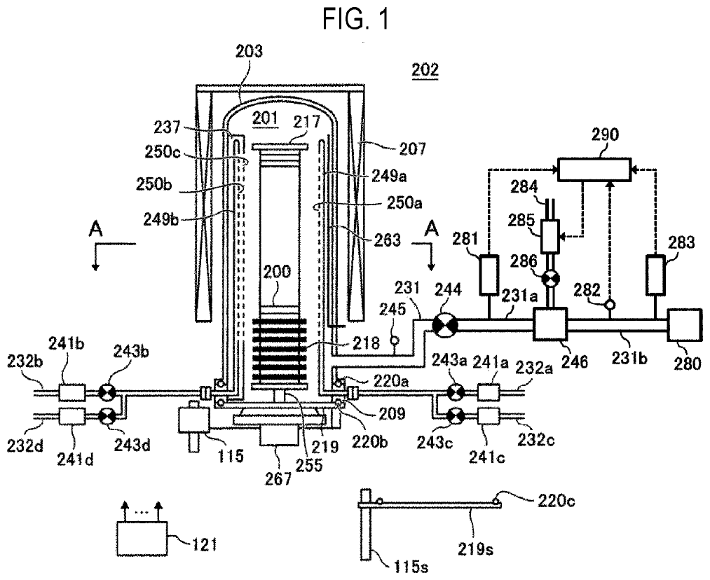

Hereinafter, embodiments of the present disclosure will be described with reference to FIGS. 1 to 6.

### (1) Configuration of Substrate Processing Apparatus (Heating Device)

FIG. 1 is a diagram to explain a substrate processing apparatus according to embodiments of the present disclosure.

As shown in FIG. 1, a process furnace 202 is a so-called vertical type furnace capable of accommodating substrates in multiple stages in a vertical direction and includes a heater 207 as a heating device (heating mechanism). The heater 207 has a cylindrical shape and is vertically installed by being supported by a heater base (not shown) as a holding plate. The heater 207 also functions as an activation mechanism (excitation part) that thermally activates (excites) a gas as will be described later.

### (Process Chamber)

Inside the heater 207, a reaction tube 203 is arranged concentrically with the heater 207. The reaction tube 203 is made of a heat-resistant material such as, for example, quartz (SiO₂), silicon carbide (SiC) or the like and is formed in a cylindrical shape with its upper end closed and its lower end opened. Under the reaction tube 203, a manifold (inlet flange) 209 is disposed concentrically with the reaction tube 203. The manifold 209 is made of a metal such as, for example, stainless steel (SUS) or the like and is formed in a cylindrical shape with its upper and lower ends opened. The upper end portion of the manifold 209 is engaged with the lower end portion of the reaction tube 203 and is configured to support the reaction tube 203. An O ring 220a as a seal member is installed between the manifold 209 and the reaction tube 203. As the manifold 209 is supported by the heater base, the reaction tube 203 is vertically installed. A process container (reaction container) mainly includes the reaction tube 203 and the manifold 209. A process chamber 201 is formed in the hollow portion which is the inside of the process container. The process chamber 201 is configured to be capable of accommodating a plurality of wafers 200 as substrates. The process container is not limited to the above configuration. Only the reaction tube 203 may be referred to as a process container in some cases.

In the process chamber 201, nozzles 249a and 249b are installed to penetrate a side wall of the manifold 209. Gas supply pipes 232a and 232b are connected to the nozzles 249a and 249b, respectively.

Mass flow controllers (MFC) 241a and 241b as flow rate controllers (flow rate control parts) and valves 243a and 243b as opening/closing valves are respectively installed in the gas supply pipes 232a and 232b in this order from the upstream side of a gas flow. Gas supply pipes 232c and 232d configured to supply an inert gas are connected to the gas supply pipes 232a and 232b, respectively, on the downstream side of the valves 243a and 243b. MFCs 241c and 241d and valves 243c and 243d are respectively installed at the gas supply pipes 232c and 232d in this order from the upstream side of a gas flow.

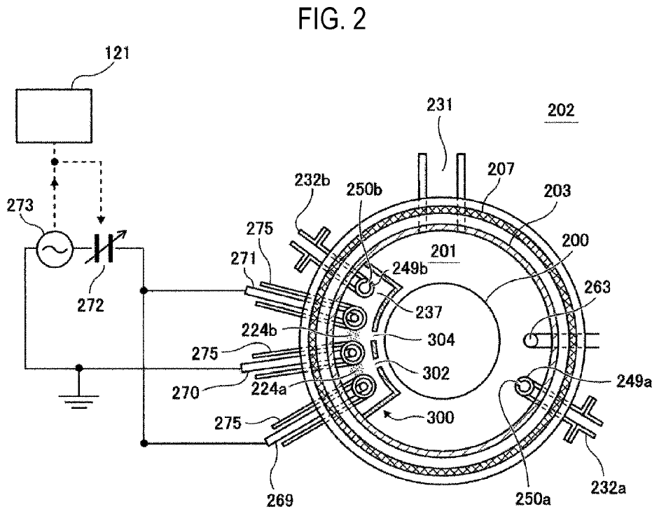

As shown in FIG. 2, the nozzle 249a is installed at a space between the inner wall of the reaction tube 203 and the wafers 200 to extend upward in a stacking direction of the wafers 200 from the lower portion of the inner wall of the reaction tube 203 to the upper portion thereof. In other words, the nozzle 249a is installed along a wafer arrangement region (mounting region) where the wafers 200 are arranged (mounted) in a region horizontally surrounding the wafer arrangement region on a lateral side of the wafer arrangement region. That is, the nozzle 249a is installed in a direction perpendicular to the surfaces (flat surfaces) of the wafers 200 on the lateral side of the end portions (peripheral edge portions) of the respective wafers 200 loaded into the process chamber 201. Gas supply holes 250a configured to supply a gas are formed on the side surface of the nozzle 249a. The gas supply holes 250a are opened to face a center of the reaction tube 203 and are capable of supplying a gas toward the wafers 200. The gas supply holes 250a are formed from the lower portion of the reaction tube 203 to the upper portion thereof. The respective gas supply holes 250a have the same opening area and are formed at the same opening pitch.

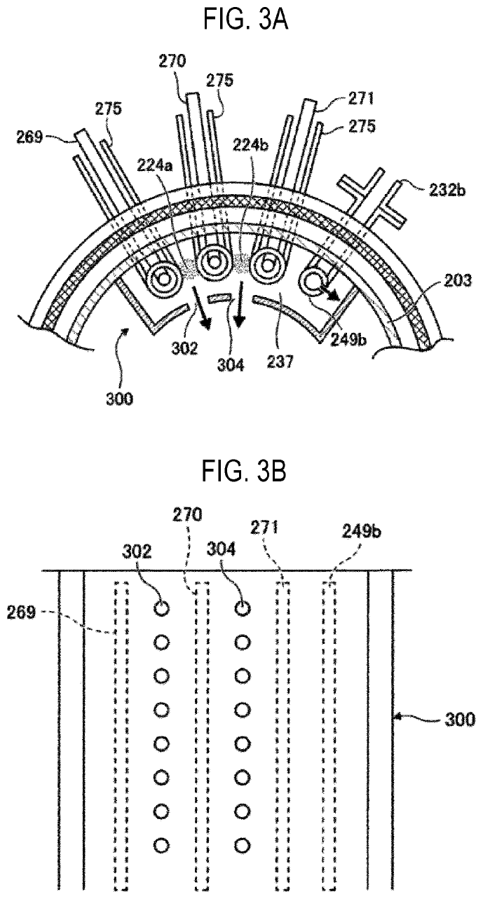

A nozzle 249b is connected to a tip of the gas supply pipe 232b. The nozzle 249b is installed in a buffer chamber 237 which is a gas dispersion space. As shown in FIG. 2, the buffer chamber 237 is installed along the stacking direction of the wafers 200 in an annular space between the inner wall of the reaction tube 203 and the wafers 200 in a plan view and in a region extending from the lower portion of the inner wall of the reaction tube 203 to the upper portion thereof. In other words, the buffer chamber 237 is formed by a buffer structure 300 to extend along the wafer arrangement region in a region horizontally surrounding the wafer arrangement region on the lateral side of the wafer arrangement region. The buffer structure 300 is made of an insulator, which is a heat-resistant material, such as quartz, SiC or the like. Gas supply ports 302 and 304 configured to supply a gas are formed at an arc-shaped wall surface of the buffer structure 300. As shown in FIGS. 2, 3A and 3B, the gas supply ports 302 and 304 are disposed at positions facing plasma generation regions 224a and 224b between rod-shaped electrodes 269 and 270 described below and between the rod-shaped electrodes 270 and 271 described below and are opened to face the center of the reaction tube 203 respectively, so that a gas can be supplied toward the wafers 200. The gas supply ports 302 and 304 are formed from the lower portion of the reaction tube 203 to the upper portion thereof. The respective gas supply ports 302 and 304 have the same opening area and are formed at the same opening pitch.

The nozzle 249b is installed to extend upward in the stacking direction of the wafers 200 from the lower portion of the inner wall of the reaction tube 203 to the upper portion thereof. In other words, the nozzle 249b is installed inside the buffer structure 300, that is, at a region horizontally surrounding the wafer arrangement region on the lateral side of the wafer arrangement region where the wafers 200 are arranged, to extend along the wafer arrangement region. That is, the nozzle 249b is installed in the direction perpendicular to the surfaces of the wafers 200 on the lateral side of the end portions of the wafers 200 loaded into the process chamber 201. Gas supply holes 250b configured to supply a gas are formed on the side surface of the nozzle 249b. The gas supply holes 250b are opened to face the wall surface formed in a radial direction with respect to the arc-shaped wall surface of the buffer structure 300. The gas supply holes 250b can supply a gas toward the wall surface. As a result, the reaction gas is dispersed in the buffer chamber 237 and is not directly blown to the rod-shaped electrodes 269 to 271, thereby suppressing generation of particles. Similar to the gas supply holes 250a, the gas supply holes 250b are formed from the lower portion of the reaction tube 203 to the upper portion thereof.

As described above, in the embodiments of the present disclosure, the gas is fed via the nozzles 249a and 249b and the buffer chamber 237 arranged in a vertically-elongated space having an annular plan-view shape, that is, a cylindrical space defined by the inner surface of the side wall of the reaction tube 203 and the inner ends of the wafers 200 arranged in the reaction tube 203. The gas is initially injected into the reaction tube 203 in the vicinity of the wafers 200 from the gas supply holes 250a and 250b and the gas supply ports 302 and 304 which are opened in the nozzles 249a and 249b and the buffer chamber 237, respectively. The main flow of the gas in the reaction tube 203 is moved in a direction parallel to the surfaces of the wafers 200, that is, in the horizontal direction. With such a configuration, it is possible to uniformly supply the gas to the respective wafers 200, and it is possible to improve the uniformity of the film thickness of the films formed on the respective wafers 200. The gas flowing on the surfaces of the wafers 200, that is, the residual gas remaining after the reaction flows toward the exhaust port, that is, toward the exhaust pipe 231 to be described later. However, the flow direction of the residual gas is appropriately specified depending on the position of the exhaust port and is not limited to the vertical direction.

From the gas supply pipe 232a, a precursor containing a predetermined element, for example, a silane precursor gas containing silicon (Si) as the predetermined element is supplied into the process chamber 201 via the MFC 241a, the valve 243a and the nozzle 249a.

The precursor gas (first precursor gas) is a precursor in a gaseous state, for example, a gas obtained by vaporizing a precursor kept in a liquid state under a room temperature and an atmospheric pressure, or a precursor kept in a gaseous state under the room temperature and the atmospheric pressure. In the subject specification, when the term “precursor” is used, it may mean a “liquid precursor in a liquid state”, a “precursor gas in a gaseous state”, or both.

As the silane precursor gas, it may be possible to use, for example, a precursor gas containing Si and a halogen element, that is, a halosilane precursor gas. The halosilane precursor is a silane precursor having a halogen group. The halogen element includes at least one element selected from the group of chlorine (CO, fluorine (F), bromine (Br) and iodine (I). That is, the halosilane precursor includes at least one halogen group selected from the group of a chloro group, a fluoro group, a bromo group and an iodo group. The halosilane precursor may be said to be a kind of halide.

As the halosilane precursor gas, it may be possible to use, for example, a precursor gas containing Si and Cl, that is, a chlorosilane precursor gas. As the chlorosilane precursor gas, it may be possible to use, for example, a dichlorosilane (SiH₂Cl₂, abbreviation: DCS) gas.

From the gas supply pipe 232b, a reactant containing an element different from the above-mentioned predetermined element, for example, a nitrogen (N)-containing gas as the reaction gas (a second precursor gas) is supplied into the process chamber 201 via the MFC 241b, the valve 243b and the nozzle 249b. As the N-containing gas, it may be possible to use, for example, a hydrogen-nitride-based gas. The hydrogen-nitride-based gas may also be a material made of only two elements, N and H, and acts as a nitriding gas, that is, an N source. As the hydrogen-nitride-based gas, it may be possible to use, for example, an ammonia (NH₃) gas.

From the gas supply pipes 232c and 232d, an inert gas, for example, a nitrogen (N₂) gas is supplied into the process chamber 201 via the MFCs 241c and 241d, the valves 243c and 243d, the gas supply pipes 232a and 232b, and the nozzles 249a and 249b, respectively.

A precursor supply system as a first gas supply system mainly includes the gas supply pipe 232a, the MFC 241a and the valve 243a. A reactant supply system as a second gas supply system mainly includes the gas supply pipe 232b, the MFC 241b and the valve 243b. An inert gas supply system mainly includes the gas supply pipes 232c and 232d, the MFCs 241c and 241d, and the valves 243c and 243d. The precursor supply system, the reactant supply system and the inert gas supply system are collectively and simply referred to as a gas supply system (gas supply part).

### (Plasma Generation Part)

As shown in FIGS. 2, 3A and 3B, three rod-shaped electrodes 269, 270 and 271 made of a conductive material and having an elongated structure are arranged in the buffer chamber 237 to extend from the lower portion of the reaction tube 203 to the upper portion thereof along the stacking direction of the wafers 200. Each of the rod-shaped electrodes 269, 270 and 271 is installed in parallel to the nozzle 249b. Each of the rod-shaped electrodes 269, 270 and 271 is protected by being covered with an electrode protective tube 275 from the upper portion to the lower portion thereof. The rod-shaped electrodes 269 and 271 disposed at both ends among the rod-shaped electrodes 269, 270 and 271 are connected to a high-frequency power source 273 via a matcher 272, and the rod-shaped electrode 270 is grounded by being connected to a ground which is a reference potential. That is, the rod-shaped electrodes, which are connected to the high-frequency power source 273, and the rod-shaped electrode to be grounded are alternately disposed. The rod-shaped electrode 270 disposed between the rod-shaped electrodes 269 and 271 connected to the high-frequency power source 273 is a grounded rod-shaped electrode and is used in common with respect to the electrodes 269 and 271. In other words, the grounded rod-shaped electrode 270 is disposed to be sandwiched between the adjacent rod-shaped electrodes 269 and 271 connected to the high-frequency power source 273. The rod-shaped electrode 269 and the rod-shaped electrode 270, and the rod-shaped electrode 271 and the rod-shaped electrode 270, are respectively configured to form a pair, thereby generating plasma. That is, the grounded rod-shaped electrode 270 is used in common for the two rod-shaped electrodes 269 and 271 disposed adjacent to the rod-shaped electrode 270 and connected to the high-frequency power source 273. By applying high-frequency (RF) power to the rod electrodes 269 and 271 from the high-frequency power source 273, plasma is generated in the plasma generation region 224a between the rod-shaped electrodes 269 and 270 and in the plasma generation region 224b between the rod-shaped electrodes 270 and 271. A plasma generation part (plasma generation device) as a plasma source mainly includes the rod-shaped electrodes 269, 270 and 271 and the electrode protective tube 275. The matcher 272 and the high-frequency power source 273 may be included in the plasma source. As will be described later, the plasma source functions as a plasma excitation part (activation mechanism) configured to plasma-excite a gas, that is, excite (activate) a gas into a plasma state.

The electrode protective tube 275 configured to be capable of being inserted into the buffer chamber 237 in a state where each of the rod electrodes 269, 270 and 271 is isolated from the atmosphere in the buffer chamber 237. In a case where an O₂ concentration in the electrode protective tube 275 is about the same as an O₂ concentration in the external air (atmosphere), the rod-shaped electrodes 269, 270 and 271 respectively inserted into the electrode protective tubes 275 may oxidized by heat generated from the heater 207. Therefore, an inert gas such as an N₂ gas or the like is filled in the electrode protective tube 275, or the inside of the electrode protective tube 275 is purged with an inert gas such as an N₂ gas or the like by using an inert gas purge mechanism. This makes it possible to reduce the O₂ concentration in the electrode protective tube 275 and to prevent oxidation of the rod-shaped electrodes 269, 270 and 271.

### (Exhaust Part)

An exhaust pipe 231 configured to exhaust the atmosphere in the process chamber 201 is installed at the reaction tube 203. A pressure sensor 245 as a pressure detector (pressure detection part) configured to detect the pressure in the process chamber 201 and an APC (Auto Pressure Controller) valve 244 as an exhaust valve (pressure regulation part) are installed at the exhaust pipe 231. The exhaust pipe 231 is connected to a vacuum pump 246 as a vacuum evacuation device and a detoxifying device 280. The APC valve 244 is a valve configured so that vacuum evacuation of the interior of the process chamber 201 and stop of the vacuum evacuation can be performed by opening and closing the APC valve 244 in a state where the vacuum pump 246 is operated, and so that the pressure in the process chamber 201 can be regulated by adjusting a valve opening degree based on the pressure information detected by the pressure sensor 245 in a state where the vacuum pump 246 is operated.

The detoxifying device 280 is, for example, a dry detoxifying device, and is configured to cause a harmful component (DCS gas) contained in the exhaust gas collected by the vacuum pump 246 to react with a chemical treating agent so that the harmful component is fixed as a safe compound to the treating agent.

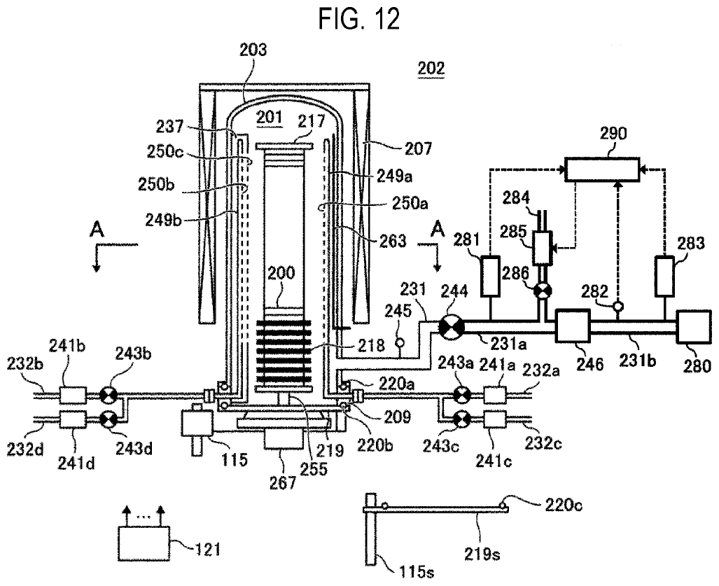

A first gas concentration measurement device (a first gas concentration sensor) 281 is installed at the exhaust pipe 231a between the outlet of the APC valve 244 and the inlet of the vacuum pump 246. A pressure measurement device (a pressure sensor) 282 and a second gas concentration measurement device (a second gas concentration sensor) 283 are installed at the exhaust pipe 231b between the outlet of the vacuum pump 246 and the inlet of the detoxifying device 280. Further, a gas supply pipe 284 is connected to the vacuum pump 246 via an MFC 285, which is a flow rate controller (flow rate control part), and a valve 286. For example, an inert gas such as a nitrogen (N₂) gas or the like is supplied to the gas supply pipe 284 as a dilution gas. That is, the gas supply pipe 284 is connected to the vacuum pump 246 and configured to supply the dilution gas into the vacuum pump 246. Instead of connecting the gas supply pipe 284 to the vacuum pump 246, the gas supply pipe 284 may be connected to the exhaust pipe 231a as shown in FIG. 12 and may be configured so that the dilution gas is supplied into the exhaust pipe 231a at a front stage of the vacuum pump 246. A dilution gas supply system that supplies a dilution gas includes the gas supply pipe 284, the MFC 285 and the valve 286.

The flow rate in the MFC 285 is controlled by a dilution controller 290 as a control part (controller). The measured value of each of the first gas concentration measurement device 281, the second gas concentration measurement device 283 and the pressure measurement device 282 may be inputted to the dilution controller 290.

The first gas concentration measurement device 281 is installed to constantly measure the gas concentration of the DCS gas (first precursor gas) in the exhaust gas passing through the exhaust pipe 231a at the front stage of the vacuum pump 246 at the time of initial value setting and at the time of operation (at the time of performing a substrate processing process). The first gas concentration measurement device 281 supplies the measurement result to the dilution controller 290.

The second gas concentration measurement device 283 is installed to set an initial value. The second gas concentration measurement device 283 measures the gas concentration of the DCS gas in the exhaust gas passing through the exhaust pipe 231b at the rear stage of the vacuum pump 246 at the time of initial value setting, and supplies the measurement result to the dilution controller 290.

The pressure measurement device 282 measures the pressure in the exhaust pipe 231b at the time of initial value setting and at the time of operation, and supplies the measurement result to the dilution controller 290.

The dilution controller 290 controls the MFC 285 to supply the dilution gas into the vacuum pump 246 (or the exhaust pipe 231a at the front stage of the vacuum pump 246), and controls the supply amount of the dilution gas so that the concentration of the DCS gas in the exhaust pipe 231b becomes 4.0% or less. This makes it possible to reliably suppress the combustion of the combustible gas at the rear stage of the vacuum pump 246.

At the time of initial value setting performed in a preparatory stage before performing the substrate processing process, the dilution controller 290 preliminarily acquires a correlation between a concentration of the DCS gas in the exhaust pipe 231a at the front stage of the vacuum pump 246 (measured by the first gas concentration measurement device 281), a concentration of the DCS gas in the exhaust pipe 231b at the rear stage of the vacuum pump 246 with respect to the flow rate of the dilution gas supplied into the vacuum pump 246 (measured by the second gas concentration measurement device 283), and a pressure in the exhaust pipe 231b at the rear stage of the vacuum pump 246 (measured by the pressure measurement device 282). This correlation is stored in a memory part (or a memory) such as, for example, a RAM 121b, a memory device 121c or an external memory device 123, which will be described later.

At the time of operation (substrate processing process), the dilution controller 290 measures the concentration of the DCS gas in the exhaust pipe 231a at the front stage of the vacuum pump 246 by the first gas concentration measurement device 281, measures the pressure in the exhaust pipe 231b at the rear stage of the vacuum pump 246 by the pressure measurement device 282, and controls the MFC 285 based on the correlation acquired at the time of initial value setting so that the dilution gas is caused to flow into the vacuum pump 246 at a flow rate corresponding to the concentration of the DCS gas measured by the first gas concentration measurement device 281 and the pressure measured by the pressure measurement device 282.

### (Initial Value Setting Procedure)

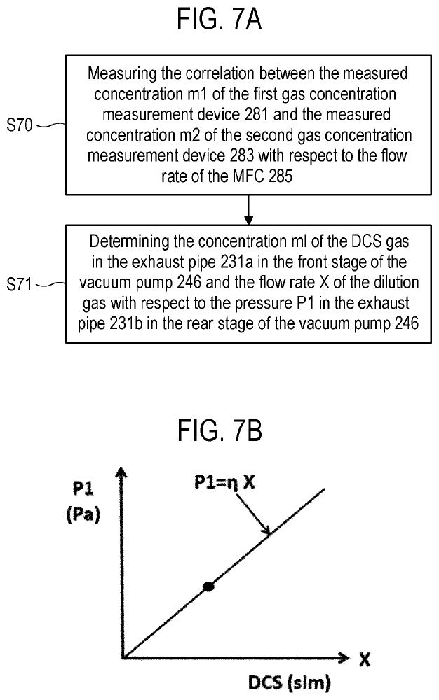

The initial value setting procedure in the dilution controller 290 will be described with reference to FIGS. 7A and 7B. FIG. 7A is a diagram showing a flow at the time of setting an initial value in the dilution controller suitably used in the embodiments of the present disclosure. FIG. 7B is a diagram illustrating an example of calculating initial setting data in the dilution controller suitably used in the embodiments of the present disclosure.

As shown in FIG. 7A, first, a correlation between a measured concentration m1 of the first gas concentration measurement device 281 and a measured concentration m2 of the second gas concentration measurement device 283 with respect to the flow rate of the MFC 285 is measured (step S70).

Next, the concentration m1 of the DCS gas in the exhaust pipe 231a at the front stage of the vacuum pump 246 and a flow rate X of the dilution gas with respect to the pressure P1 in the exhaust pipe 231b at the rear stage of the vacuum pump 246 are determined (step S71).

The calculation of the initial setting data is performed as follows.

1) First, the dilution controller 290 controls the MFC 285 to set the inflow amount of the dilution gas (N₂ gas) to α (slm).

2) Next, the concentration of the DCS gas in the exhaust pipe 231a at the front stage of the vacuum pump 246 is measured by the first gas concentration measurement device 281. Further, the concentration of the DCS gas in the exhaust pipe 231b at the rear stage of the vacuum pump 246 is measured by the second gas concentration measurement device 283. The measurement results are as follows.

Concentration of DCS gas in exhaust pipe 231a (on primary side): m1(%)

Concentration of DCS gas in exhaust pipe 231b (on secondary side): m2(%)

This measurement is performed in step S70.

3) The flow rate X (slm) of the inflowing DCS gas is calculated by using α, m1 and m2.

X/(X+Y)=m1/100 (Equation 1)

X/(α+X+Y)=m2/100 (Equation 2)

In the above equations, X is the flow rate (slm) of the DCS gas, and Y is the flow rate (slm) of other gases.

4) The coefficient η is calculated assuming that the flow rate X of the DCS gas is proportional to the measured pressure P1 (Pa) measured by the pressure measurement device 282 (assuming that the DCS gas inflow amount X∝the measured pressure P1), and the correlation (P1=ηX) is plotted on the graph as shown in FIG. 7B. In the graph of FIG. 7B, the vertical axis represents the measured pressure P1 (Pa), and the horizontal axis represents the flow rate X (slm) of the DCS gas.

As a result, the correlation between the measured concentration m1 of the first gas concentration measurement device 281, the measured concentration m2 of the second gas concentration measurement device 283 and the inflow amount X of the DCS gas with respect to the measured pressure P1 measured by the pressure measurement device 282 can be obtained as initial value setting data. The obtained correlation is stored in a memory device such as a RAM 121b, a memory device 121c or an external memory device 123, which will be described later. Therefore, the initial value setting procedure may be said to be a process or procedure of acquiring the correlation and storing it in the memory part. In the step or procedure of acquiring the correlation and storing the correlation in the storage unit, the correlation between a concentration of the DCS gas in the exhaust pipe 231a at the front stage of the vacuum pump 246, which is measured by the first gas concentration measurement device 281, a concentration of the DCS gas in the exhaust pipe 231b at the rear stage of the vacuum pump 246 with respect to the flow rate of the dilution gas supplied into the vacuum pump 246, which is measured by the second gas concentration measurement device 283, and a pressure in the exhaust pipe 231b at the rear stage of the vacuum pump 246, which is measured by the pressure measurement device 282, is preliminarily acquired and stored in the RAM 121b.

### (Procedure at the Time of Operation)

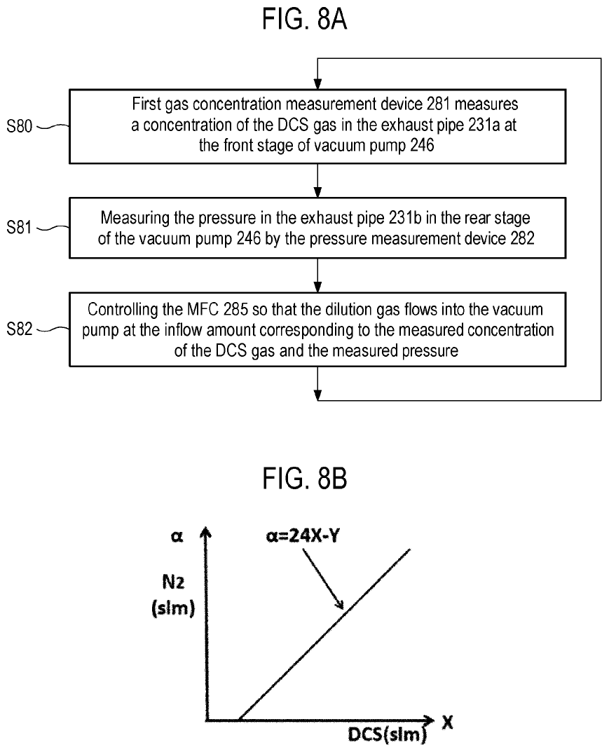

The procedure at the time of operation in the dilution controller 290 will be described with reference to FIGS. 8A and 8B. FIG. 8A is a diagram showing a control flow at the time of operating the dilution controller suitably used in the embodiments of the present disclosure. FIG. 8B is a diagram illustrating an example of calculating an inflow amount of a dilution gas (N₂) at the time of operating the dilution controller suitably used in the embodiments of the present disclosure.

As shown in FIG. 8A, first, the first gas concentration measurement device 281 measures a concentration of the DCS gas in the exhaust pipe 231a at the front stage of the vacuum pump 246 (step S80). The concentration m1 of the DCS gas in the exhaust pipe 231a measured by the first gas concentration measurement device 281 is sent to the dilution controller 290.

Next, the pressure in the exhaust pipe 231b at the rear stage of the vacuum pump 246 is measured by the pressure measurement device 282 (step S81). The pressure P1 measured by the pressure measurement device 282 is sent to the dilution controller 290.

Then, the dilution controller 290 controls the MFC 285 and opens the valve 286 such that the dilution gas flows into the vacuum pump 246 (or the exhaust pipe 231a at the front stage of the vacuum pump 246) at the inflow amount X of the dilution gas corresponding to the measured concentration m1 of the DCS gas and the measured pressure P1 (step S82). When the exhaust of the DCS gas is completed, the valve 286 is closed to stop the supply of the dilution gas.

By repeating the above steps (S80, S81 and S82), the substrate processing process is performed.

Calculation of the inflow amount X of the dilution gas (N₂) at the time of operation (at the time of performing the substrate processing process) can be performed as follows.

1) From the pressure P1 measured by the pressure measurement device 282 and the concentration m1 of the DCS gas in the exhaust pipe 231a measured by the first gas concentration measurement device 281, the values of the flow rate X of the DCS gas and the flow rate Y of other gases are calculated by using the plotted graph of the correlation (P1=ηX) shown in FIG. 7B and Equation 1.

X=P1/η (Equation 3)

Y=((100-m1)X)/m1=((100-m1)P1/η)/m1 (Equation 4)

2) By using the calculated flow rate X of the DCS gas and the calculated flow rate Y of other gases, the inflow amount α (slm) of the required dilution gas (N₂) is calculated by the following Equation 5.

X/(α+X+Y)=4/100 (Equation 5)

α=24X−Y (Equation 6)

Equation 5 is obtained by substituting m2=4(%) into the value of m2 of Equation 2. By modifying Equation 5, it is possible to obtain Equation 6. Equation 6 is shown in the graph of FIG. 8B. In the graph of FIG. 8B, the vertical axis represents the inflow amount α (slm) of the dilution gas (N₂), and the horizontal axis represents the flow rate X (slm) of the DCS gas.

Therefore, the inflow amount α (slm) of the dilution gas (N₂) can be calculated by substituting the values of Equations 3 and 4 into Equation 6. The dilution controller 290 controls the MFC 285 based on the inflow amount α (slm) of the dilution gas (N₂) obtained by Equation 6.

Accordingly, the dilution controller 290 can control the MFC 285 to supply the dilution gas to the vacuum pump 246 (or the exhaust pipe 231a at the front stage of the vacuum pump 246) and can control the supply amount of the inert gas so that the concentration of the DCS gas in the exhaust pipe 231b becomes 4.0% or less. Therefore, it is possible to reliably suppress the combustion of the combustible gas (DCS gas) at the rear stage of the vacuum pump 246.

An exhaust system mainly includes the exhaust pipes 231, 231a and 231b, the APC valve 244, the pressure sensor 245, the first gas concentration measurement device 281 and the pressure measurement device 282. The vacuum pump 246, the second gas concentration measurement device 283, the gas supply pipe 284, the MFC 285 and the dilution controller 290 may be included in the exhaust system. A dilution gas supply system includes the gas supply pipe 284 and the MFC 285. The vacuum pump 246, the dilution controller 290, the first gas concentration measurement device 281, the pressure measurement device 282 and the second gas concentration measurement device 283 may be included in the dilution gas supply system.

The exhaust pipe 231 is not limited to being provided in the reaction tube 203, and may be installed at the manifold 209 just like the nozzles 249a and 249b.

A seal cap 219 as a furnace opening lid capable of airtightly closing the lower end opening of the manifold 209 is installed below the manifold 209. The seal cap 219 is configured to make contact with the lower end of the manifold 209 from the lower side in the vertical direction. The seal cap 219 is made of a metal such as, for example, stainless steel or the like and is formed in a disc shape. On the upper surface of the seal cap 219, there is installed an O ring 220b as a seal member which makes contact with the lower end of the manifold 209. On the side of the seal cap 219 opposite to the process chamber 201, there is installed a rotation mechanism 267 configured to rotate a boat 217 to be described later. A rotating shaft 255 of the rotating mechanism 267 passes through the seal cap 219 and is connected to the boat 217. The rotation mechanism 267 is configured to rotate the wafers 200 by rotating the boat 217. The seal cap 219 is configured to be raised or lowered in the vertical direction by a boat elevator 115 as an elevating mechanism vertically installed outside the reaction tube 203. The boat elevator 115 is configured to load or unload the boat 217 into or from the process chamber 201 by raising or lowering the seal cap 219. The boat elevator 115 is configured as a transfer device (transfer mechanism) configured to transfer the boat 217, that is, the wafers 200 into or from the process chamber 201. Further, under the manifold 209, there is installed a shutter 219s as a furnace opening lid capable of airtightly closing the lower end opening of the manifold 209 while lowering the seal cap 219 by the boat elevator 115. The shutter 219s is made of a metal such as, for example, stainless steel or the like and is formed in a disk shape. On the upper surface of the shutter 219s, there is installed an O-ring 220c as a seal member which makes contact with the lower end of the manifold 209. The opening/closing operations (the elevating operation, the rotating operation and the like) of the shutter 219s are controlled by a shutter opening/closing mechanism 115s.

### (Substrate Support Tool)

As shown in FIG. 1, the boat 217 serving as a substrate support is configured to support a plurality of wafers 200, for example, 25 to 200 wafers 200, in such a state that the wafers 200 are arranged in a horizontal posture and in multiple stages along a vertical direction with centers of the wafers 200 aligned with one another, that is, the wafers 200 are arranged at predetermined intervals. The boat 217 is made of a heat-resistant material such as, for example, quartz or SiC. Heat insulating plates 218 made of a heat-resistant material such as, for example, quartz or SiC are disposed at multiple stages in the lower portion of the boat 217.

As shown in FIG. 2, in the reaction tube 203, there is installed a temperature sensor 263 as a temperature detector. By adjusting a degree of electric power supplied to the heater 207 based on the temperature information detected by the temperature sensor 263, the temperature inside the process chamber 201 is controlled to have a desired temperature distribution. The temperature sensor 263 is installed along the inner wall of the reaction tube 203, like the nozzles 249a and 249b.

### (Control Device)

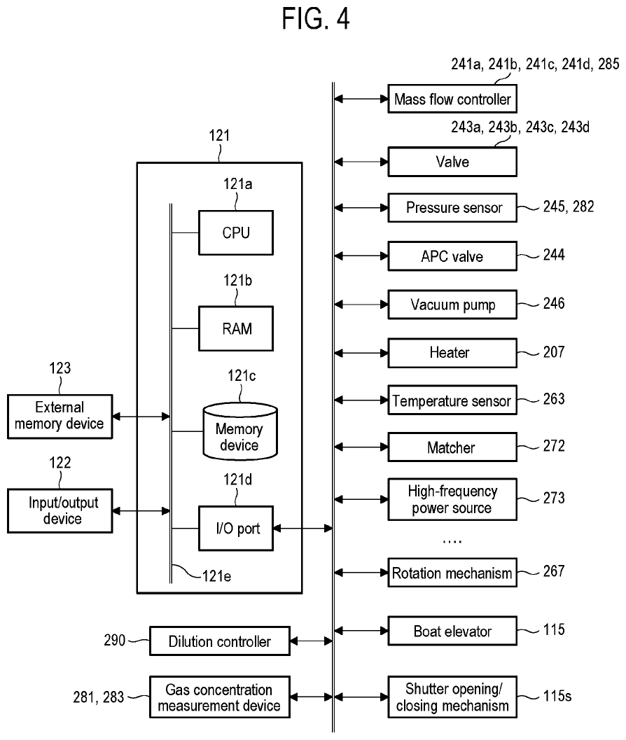

Next, the control device will be described with reference to FIG. 4. As shown in FIG. 4, the controller 121 as a control part (control device) is configured as a computer including a CPU (Central Processing Unit) 121a, a RAM (Random Access Memory) 121b, a memory device 121c and an I/O port 121d. The RAM 121b, the memory device 121c, and the I/O port 121d are configured to be capable of exchanging data with the CPU 121a via an internal bus 121e. An input/output device 122 configured as, for example, a touch panel or the like is connected to the controller 121.

The memory device 121c includes, for example, a flash memory, a hard disc drive (HDD), or the like. A control program for controlling the operation of the substrate processing apparatus, a process recipe in which the correlation described above and the procedures and conditions of a film-forming process to be described later are written, and the like are readably stored in the memory device 121c. The process recipe is a combination that can obtain a predetermined result by causing the controller 121 to execute each procedure in various processes (film-forming process) which will be described later. The process recipe functions as a program. Hereinafter, the process recipe, the control program, and the like will be generally and simply referred to as a “program.” Further, the process recipe is simply referred to as a recipe. When the term “program” is used herein, it may indicate a case of including only the process recipe, a case of including only the control program, or a case of including both the process recipe and the control program. The RAM 121b is configured as a memory area (work area) in which the program read by the CPU 121a, the correlation described above, data and the like are temporarily stored.

The I/O port 121d is connected to the MFCs 241a to 241d and 285, the valves 243a to 243d, the pressure sensors 245 and 282, the APC valve 244, the vacuum pump 246, the heater 207, the temperature sensor 263, the matcher 272, the high-frequency power source 273, the rotation mechanism 267, the boat elevator 115, the shutter opening/closing mechanism 115s, the dilution controller 290, the concentration measurement devices 281 and 283, and the like.

The CPU 121a is configured to read the control program from the memory device 121c and execute the same. The CPU 121a is also configured to read the recipe from the memory device 121c according to an input of an operation command from the input/output device 122, and the like. The CPU 121a is configured to control, according to the contents of the process recipe thus read, the operation of the rotation mechanism 267, the flow rate adjustment operation of various gases by the MFCs 241a to 241d, the opening/closing operation of the valves 243a to 243d, the adjustment operation of the high-frequency power source 273 based on impedance monitoring, the opening/closing operation of the APC valve 244, the pressure regulation operation performed by the APC valve 244 based on the pressure sensor 245, the start and stop of the vacuum pump 246, the temperature adjustment operation performed by the heater 207 based on the temperature sensor 263, the gas flow rate adjustment operation by the MFC 285 of the dilution controller 290 based on the concentration measurement operations of the concentration measurement devices 281 and 283, and the measurement operations of the concentration measurement device 281 and the pressure sensor 282, the forward and reverse rotation of the boat 217 by the rotation mechanism 267, the adjustment operation of the rotation angle and rotation speed of the boat 217, the operation of raising or lowering the boat 217 by the boat elevator 115, and the like.

The controller 121 may be configured by installing, in a computer, the above-described program stored in an external memory device (e.g., a magnetic disk such as a hard disk or the like, an optical disk such as a CD or the like, a magneto-optical disk such as an MO or the like, or a semiconductor memory such as a USB memory or the like) 123. The memory device 121c or the external memory device 123 is configured as a computer-readable recording medium. Hereinafter, the memory device 121c and the external memory device 123 will be generally and simply referred to as a “recording medium.” When the term “recording medium” is used herein, it may indicate a case of including only the memory device 121c, a case of including only the external memory device 123, or a case of including both the memory device 121c and the external memory device 123. The provision of the program to the computer may be performed by using a communication means such as the Internet or a dedicated line without using the external memory device 123.

### (2) Substrate Processing Process

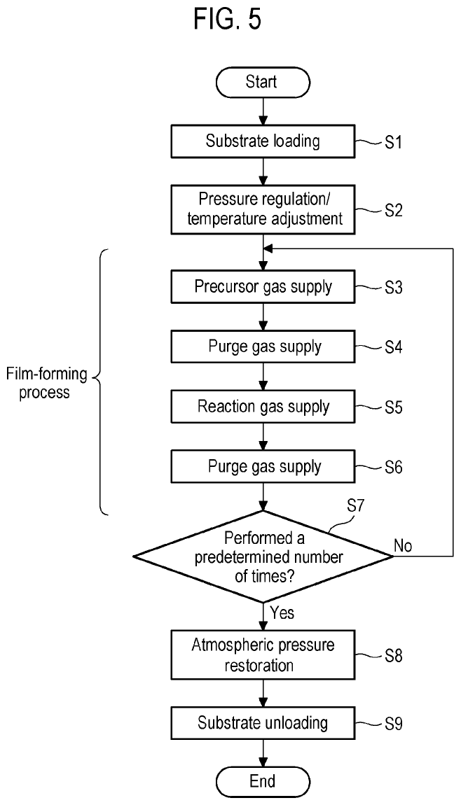

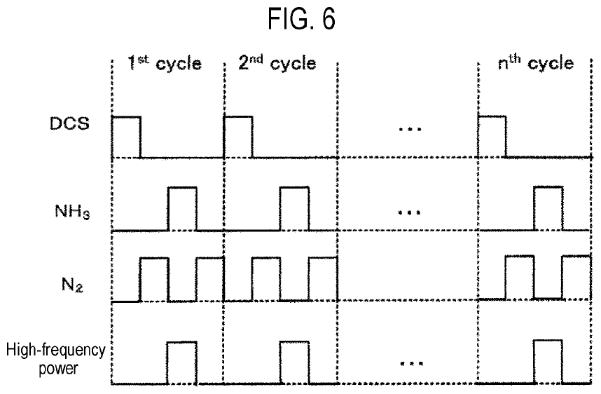

Next, a process of forming a thin film on a wafer 200 by using the substrate processing apparatus 100 will be described as one of semiconductor device manufacturing processes (manufacturing methods) with reference to FIGS. 5 and 6. In the following description, the operations of the respective parts constituting the substrate processing apparatus are controlled by the controller 121.

Description will now be made on an example where a silicon nitride film (SiN film) as a film containing Si and N is formed on a wafer 200 by performing a step of supplying a DCS gas as a precursor gas (first precursor gas) and a step of supplying a plasma-excited NH₃ gas as a reaction gas (second precursor gas), a predetermined number of times (one or more times), in a non-simultaneous manner, that is, without synchronization. Moreover, for example, a predetermined film may be formed in advance on the wafer 200. In addition, a predetermined pattern may be formed in advance on the wafer 200 or the predetermined film.

In this specification, the process flow of the film-forming process shown in FIG. 6 may be denoted as follows for the sake of convenience. Similar notations are also used in the following modifications and other embodiments.

(DCS→NH₃*)×n⇒SiN

When the term “wafer” is used herein, it may refer to “a wafer itself” or “a laminated body of a wafer and a predetermined layer or film formed on the surface of the wafer.” Further, when the phrase “a surface of a wafer” is used herein, it may refer to “a surface of a wafer itself” or “a surface of a predetermined layer or the like formed on a wafer.” Further, the expression “a predetermined layer is formed on a wafer” as used herein may mean that “a predetermined layer is directly formed on a surface of a wafer itself” or that “a predetermined layer is formed on a layer or the like formed on a wafer.” In addition, when the term “substrate” is used herein, it may be synonymous with the term “wafer.”

### (Loading Step: S1)

When a plurality of wafers 200 is charged on the boat 217 (wafer charging), the shutter 219s is moved by the shutter opening/closing mechanism 115s to open the lower end opening of the manifold 209 (shutter open). Thereafter, as shown in FIG. 1, the boat 217 that supports the plurality of wafers 200 is lifted up by the boat elevator 115 and is loaded into the process chamber 201 (boat loading). In this state, the seal cap 219 seals the lower end of the manifold 209 via the O-ring 220b.

### (Pressure Regulation/Temperature Adjustment Step: S2)

The interior of the process chamber 201, that is, the space in which the wafers 200 exist, is vacuum-evacuated (depressurizing-evacuated) by the vacuum pump 246 to reach a desired pressure (degree of vacuum). At this time, the pressure in the process chamber 201 is measured by the pressure sensor 245. The APC valve 244 is feedback-controlled based on the measured pressure information. The vacuum pump 246 is kept operated at least until the film-forming step described later is completed.

Further, the wafer 200 in the process chamber 201 is heated by the heater 207 to have a desired temperature. At this time, the supply of electric power to the heater 207 is feedback-controlled based on the temperature information detected by the temperature sensor 263 so that the inside of the process chamber 201 has a desired temperature distribution. The heating of the inside of the process chamber 201 by the heater 207 is continuously performed at least until the film-forming step to be described later is completed. However, in the case where the film-forming step is performed under a temperature condition of room temperature or lower, the heating of the inside of the process chamber 201 by the heater 207 may not be performed. When only the processing at such a temperature is performed, the heater 207 may not be provided and the heater 207 may not be installed in the substrate processing apparatus. In this case, it is possible to simplify the configuration of the substrate processing apparatus.

Subsequently, the rotation of the boat 217 and the wafers 200 by the rotation mechanism 267 is started. The rotation of the boat 217 and the wafers 200 by the rotation mechanism 267 is continuously performed at least until the film-forming step is completed.

### (Film-Forming Step: S3, S4, S5 and S6)

Thereafter, a film-forming step is performed by sequentially executing steps S3, S4, S5 and S6.

### (Precursor Gas Supply Step: S3 and S4)

In step S3, a DCS gas as a first precursor gas is supplied to the wafer 200 in the process chamber 201.

The valve 243a is opened, and the DCS gas is allowed to flow into the gas supply pipe 232a. The flow rate of the DCS gas is adjusted by the MFC 241a. The DCS gas is supplied from the gas supply holes 250a into the process chamber 201 via the nozzle 249a and is exhausted from the exhaust pipes 231, 231a and 231b. At the same time, the valve 243c is opened to allow an N₂ gas to flow into the gas supply pipe 232c. The flow rate of the N₂ gas is adjusted by the MFC 241c. The N₂ gas is supplied into the process chamber 201 together with the DCS gas and is exhausted from the exhaust pipes 231, 231a and 231b. At this time, the control flow (steps S80, S81 and S82) of the dilution controller 290 described with reference to FIG. 8A is executed. Therefore, step S3 includes a process or procedure of supplying the DCS gas to the wafers 200 in the process chamber 201 from the first gas supply system (the gas supply pipe 232a, the MFC 241a and the valve 243a), and a process or procedure of exhausting the DCS gas in the process chamber 201. In the process or procedure of exhausting the DCS gas in the process chamber 201, the DCS gas in the process chamber 201 is exhausted while supplying a dilution gas into the vacuum pump 246 or the exhaust pipe 231a at the front stage of the vacuum pump 246 at a flow rate corresponding to the concentration of the DCS gas, which is measured by the first gas concentration measurement device 281, and the pressure in the exhaust pipe 231b at the rear stage of the vacuum pump 246, which is measured by the pressure measurement device 282. In the process or procedure of exhausting the DCS gas in the process chamber 201, the concentration of the DCS gas is measured by the first gas concentration measurement device 281, and the pressure in the exhaust pipe 231b at the rear stage of the vacuum pump 246 is measured. Based on the correlation stored in the RAM 121b, the dilution gas is supplied into the vacuum pump 246 or the exhaust pipe 231a at the front stage of the vacuum pump 246 at a flow rate corresponding to the concentration of the DCS gas measured by the first gas concentration measurement device 281 and the pressure measured by the pressure measurement device 282.

The valve 243d is opened to allow an N₂ gas to flow into the gas supply pipe 232d to suppress the intrusion of the DCS gas into the nozzle 249b. The N₂ gas is supplied into the process chamber 201 via the gas supply pipe 232b and the nozzle 249b and is exhausted from the exhaust pipe 231.

The supply flow rate of the DCS gas controlled by the MFC 241a is set to a flow rate falling within a range of, for example, 1 sccm or more and 6000 sccm or less, specifically 2000 sccm or more and 3000 sccm or less in some embodiments. The supply flow rate of the N₂ gas controlled by the MFCs 241c and 241d is set to a flow rate falling within a range of, for example, 100 sccm or more and 10000 sccm or less. The pressure in the process chamber 201 is set to a pressure falling within a range of, for example, 1 Pa or more and 2666 Pa or less, specifically 665 Pa or more and 1333 Pa or less in some embodiments. The time for which the wafers 200 are exposed to the DCS gas is set to a time falling within a range of, for example, 1 second or more and 10 seconds or less, specifically 1 second or more and 3 seconds or less in some embodiments. The time for which the wafers 200 are exposed to the DCS gas depends on the film thickness.

The temperature of the heater 207 is set so that the temperature of the wafers 200 becomes a temperature falling within a range of, for example, 0 degrees C. or more and 700 degrees C. or less, specifically a room temperature (25 degrees C.) or more and to 550 degrees C. or less, more specifically 40 degrees C. or more and 500 degrees C. or less in some embodiments. By setting the temperature of the wafer 200 to 700 degrees C. or less, specifically 550 degrees C. or less, or more specifically 500 degrees C. or less as in the embodiments of the present disclosure, it is possible to reduce the amount of heat applied to the wafers 200 and to satisfactorily control thermal history undergone by the wafers 200.

By supplying the DCS gas to the wafer 200 under the aforementioned conditions, an Si-containing layer is formed on the wafer 200 (on a base film on the surface of the wafer 200). The Si-containing layer may contain Cl or H in addition to Si. The Si-containing layer is formed on the outermost surface of the wafer 200 by physically adsorbing DCS, chemically adsorbing a substance obtained by partial decomposition of DCS, or depositing Si by thermal decomposition of DCS. That is, the Si-containing layer may be an adsorption layer (physical adsorption layer or chemical adsorption layer) of DCS or a substance obtained by partial decomposition of DCS, or may be an Si deposition layer (Si layer).

After the Si-containing layer is formed, the valve 243a is closed, and the supply of the DCS gas into the process chamber 201 is stopped. At this time, the APC valve 244 is kept opened, the inside of the process chamber 201 is vacuum-evacuated by the vacuum pump 246, and the DCS gas unreacted or contributed to the formation of the Si-containing layer, the reaction byproduct and the like, which remain in the process chamber 201, are removed from the process chamber 201 (S4). Further, the valves 243c and 243d are kept opened, and the supply of the N₂ gas into the process chamber 201 is maintained. The N₂ gas acts as a purge gas. At this time, the control flow (steps S80, S81 and S82) of the dilution controller 290 described with reference to FIG. 8A may be performed. Step S4 may be omitted.

As the precursor gas, in addition to the DCS gas, it may be possible to suitably use: various aminosilane precursor gases such as a tetrakisdimethylaminosilane (Si[N(CH₃)₂]₄, abbreviation: 4DMAS) gas, a trisdimethylaminosilane (Si[N(CH₃)₂]₃H, abbreviation: 3DMAS) gas, a bisdimethylaminosilane (Si[N(CH₃)₂]₂H₂, abbreviation: BDMAS) gas, a bisdiethylaminosilane (Si[N(C₂H₅)₂]₂H₂, abbreviation: BDEAS) gas, a bis-tertiary-butyl aminosilane (SiH₂[NH(C₄H₉)]₂, abbreviation: BTBAS) gas, a dimethylaminosilane (DMAS) gas, a diethylaminosilane (DEAS) gas, a dipropylaminosilane (DPAS) gas, a diisopropylaminosilane (DIPAS) gas, a butylaminosilane (BAS) gas, a hexamethyldisilazane (HMDS) gas and the like; inorganic halosilane precursor gases such as a monochlorosilane (SiH₃Cl, abbreviation: MCS) gas, a trichlorosilane (SiHCl₃, abbreviation: TCS) gas, a tetrachlorosilane (SiCl₄, abbreviation: STC) gas, a hexachlorodisilane (Si₂Cl₆, abbreviation: HCDS) gas, an octachlorotrisilane (Si₃Cl₈, abbreviation: OCTS) gas and the like; and halogen-group-free inorganic silane precursor gases such as a monosilane (SiH₄, abbreviation: MS) gas, a disilane (Si₂H₆, abbreviation: DS) gas, a trisilane (Si₃H₈, abbreviation: TS) gas and the like.

As the inert gas, in addition to the N₂ gas, it may be possible to use a rare gas such as an Ar gas, a He gas, a Ne gas, a Xe gas or the like.

### (Reaction Gas Supply Step: S5 and S6)

After the film-forming process is finished, a plasma-excited NH₃ gas as a reaction gas is supplied to the wafer 200 in the process chamber 201 (S5). That is, the reaction gas supply step S5 may be said to be a process or procedure of supplying a second precursor gas (NH₃ gas) to the wafer 200 in the process chamber 201 from the second gas supply system (the gas supply pipe 232b, the MFC 241b and the valve 243b).

In this step, the opening and closing control of the valves 243b to 243d is performed in the same procedure as the opening and closing control of the valves 243a, 243c and 243d in step S3. The flow rate of the NH₃ gas is adjusted by the MFC 241b. The NH₃ gas is supplied into the buffer chamber 237 via the nozzle 249b. At this time, high-frequency power is supplied between the rod-shaped electrodes 269, 270 and 271. The NH₃ gas supplied into the buffer chamber 237 is excited into a plasma state (activated into plasma). The excited NH₃ gas is supplied into the process chamber 201 as active species (NH₃*) and is exhausted from the exhaust pipe 231.

The supply flow rate of the NH₃ gas controlled by the MFC 241b is set to a flow rate falling within a range of, for example, 100 sccm or more and 10000 sccm or less, specifically 1000 sccm or more and 2000 sccm or less in some embodiments. The high-frequency power applied to the rod-shaped electrodes 269, 270 and 271 is set to electric power falling within a range of, for example, 50 W or more and 600 W or less. The pressure in the process chamber 201 is set to a pressure falling within a range of, for example, 1 Pa or more and 500 Pa or less. By using plasma, it is possible to activate the NH₃ gas even in a case where the pressure in the process chamber 201 is set to fall within such a relatively low pressure band. The time for which the active species obtained by exciting the NH₃ gas with plasma is supplied to the wafer 200, that is, gas supply time (irradiation time) is set to a time falling within a range of, for example, 1 second or more and 180 seconds or less, specifically 1 second or more and 60 seconds or less in some embodiments. Other processing conditions are the same as those of step S3 described above.

By supplying the NH₃ gas to the wafer 200 under the aforementioned conditions, the Si-containing layer formed on the wafer 200 is nitrided by plasma. At this time, an Si—Cl bond and an Si—H bond of the Si-containing layer are broken by the energy of the plasma-excited NH₃ gas. Cl and H whose bond with Si is broken are desorbed from the Si-containing layer. Then, Si in the Si-containing layer that has a dangling bond due to desorption of Cl or the like is bonded to N contained in the NH₃ gas, thereby forming a Si—N bond. As the reaction goes forward, the Si-containing layer is changed (modified) to a layer containing Si and N, that is, a silicon nitride layer (SiN layer).

The NH₃ gas needs to be supplied by plasma-exciting the same to modify the Si-containing layer into the SiN layer. This is because, even in a case where the NH₃ gas is supplied in a non-plasma atmosphere, the energy to nitride the Si-containing layer is insufficient in the aforementioned temperature range, whereby it is difficult to sufficiently desorb Cl or H from the Si-containing layer or to sufficiently nitride the Si-containing layer to increase Si—N bonds.

After changing the Si-containing layer to the SiN layer, the valve 243b is closed and the supply of the NH₃ gas is stopped. Further, the supply of the high-frequency power to the rod-shaped electrodes 269, 270 and 271 is stopped. Then, the NH₃ gas and the reaction byproducts remaining in the process chamber 201 are removed from the inside of the process chamber 201 by the same processing procedure and processing conditions as those of step S4 (S6). Step S6 may be said to be a process or a procedure of exhausting the second precursor gas (NH₃ gas) in the process chamber 201. Step S6 may be omitted.

As the nitriding agent, that is, the NH₃-containing gas to be plasma-excited, in addition to the NH₃ gas, it may be possible to use a diazene (N₂H₂) gas, a hydrazine (N₂H₄) gas, an N₃H₈ gas or the like.

As the inert gas, in addition to the N₂ gas, it may be possible to use, for example, various rare gases exemplified in step S4.

### (Performing a Predetermined Number of Times: S7)

By performing a cycle a predetermined number of times (n times), that is, one or more times, wherein the cycle includes performing the aforementioned steps S3, S4, S5 and S6 in a non-simultaneous manner, i.e., without synchronization, in this order (S7), it is possible to form a SiN film having a predetermined composition and a predetermined film thickness on the wafer 200. The aforementioned cycle may be repeated a plurality of times in some embodiments. That is, a thickness of the SiN layer formed per cycle is set smaller than a desired film thickness, and the aforementioned cycle may be repeated a plurality of times until a film thickness of a SiN film formed by stacking the SiN layer reaches the desired film thickness in some embodiments.

### (Atmospheric Pressure Restoration Step: S8)

When the above-described film-forming process is completed, an N₂ gas as an inert gas is supplied into the process chamber 201 from each of the gas supply pipes 232c and 232d, and is exhausted from the exhaust pipe 231. As a result, the interior of the process chamber 201 is purged with the inert gas, and the gas or the like remaining in the process chamber 201 is removed from the inside of the process chamber 201 (inert gas purge). Thereafter, the atmosphere in the process chamber 201 is replaced with the inert gas (inert gas replacement), and the pressure in the process chamber 201 is restored to the atmospheric pressure (S8). At this time, a control flow (steps S80, S81 and S82) of the dilution controller 290 described with reference to FIG. 8A may be performed.

### (Unloading Step: S9)

Thereafter, the seal cap 219 is lowered by the boat elevator 115, the lower end of the manifold 209 is opened, and the processed wafers 200 are unloaded from the lower end of the manifold 209 to the outside of the reaction tube 203 while being supported by the boat 217 (boat unloading) (S9). After the boat unloading, the shutter 219s is moved, and the lower end opening of the manifold 209 is sealed by the shutter 219s via the O ring 220c (shutter closing). After the processed wafers 200 are unloaded to the outside of the reaction tube 203, they are taken out from the boat 217 (wafer discharging). After the wafer discharging, the empty boat 217 may be loaded into the process chamber 201.

### (3) Effects of the Present Embodiment

According to the present embodiment, one or more of the following effects may be obtained.

(a) The exhaust system of the substrate processing apparatus includes the gas concentration measurement device 281 that measures the concentration of the first precursor gas (DCS gas) in the exhaust pipe 231a at the front stage of the vacuum pump 246, and the pressure measurement device 282 that measures the pressure in the exhaust pipe 231b at the rear stage of the vacuum pump 246. The dilution gas is supplied to the vacuum pump 246 at a flow rate corresponding to the measured concentration of the first precursor gas and the measured pressure in the exhaust pipe 231b at the rear stage of the vacuum pump 246. The first precursor gas is diluted with the dilution gas and then exhausted. This makes it possible to reliably suppress the combustion of the combustible gas at the rear stage of the vacuum pump.

(b) The correlation between the concentration of the DCS gas in the exhaust pipe 231a at the front stage of the vacuum pump 246, the concentration of the DCS gas in the exhaust pipe 231b at the rear stage of the vacuum pump 246 with respect to the flow rate of the dilution gas supplied into the vacuum pump 246, and the pressure in the exhaust pipe 231b at the rear stage of the vacuum pump 246 is acquired in advance (see FIGS. 7A and 7B). The concentration of the DCS gas in the exhaust pipe 231a at the front stage of the vacuum pump 246 and the pressure in the exhaust pipe 231b at the rear stage of the vacuum pump 246 are measured, and the dilution gas is caused to flow into the vacuum pump 246 at a flow rate corresponding to the measured concentration of the DCS gas and the measured pressure. This makes it possible to reliably suppress the combustion of the combustible gas at the rear stage of the vacuum pump 246.

(c) By supplying the dilution gas into the vacuum pump 246 or the exhaust pipe 231a at the front stage of the vacuum pump 246, it is possible to control the supply amount of the inert gas so that the concentration of the DCS gas in the exhaust pipe 231b at the rear stage of the vacuum pump 246 becomes 4.0% or less. This makes it possible to reliably suppress the combustion of the combustible gas at the rear stage of the vacuum pump 246.

### (Modification)

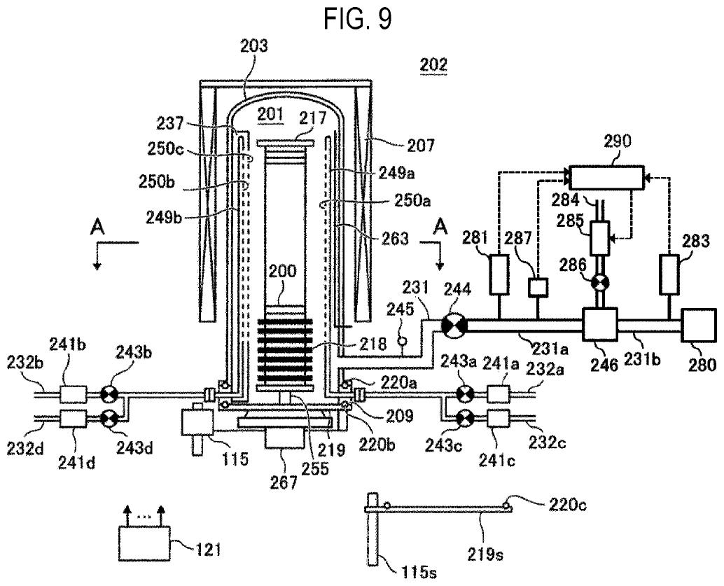

Next, a modification of the embodiments of the present disclosure will be described with reference to FIG. 9. In this modification, only the parts different from those of the above-described embodiments will be described below, and the same parts will not be described. In the above-described embodiments, the configuration in which the pressure measurement device 282 is installed at the exhaust pipe 231b in the rear stage of the vacuum pump 246 has been described in detail. In this modification, the pressure measurement device 282 is not installed, and a flow rate measurement device 287 configured to measure a flow rate is installed at the exhaust pipe 231a at the front stage of the vacuum pump 246. The measurement result of the flow rate measurement device 287 is sent to the dilution controller 290. Other configurations are similar to those of FIG. 1 and, therefore, the description thereof is omitted.

### (Initial Value Setting Procedure)

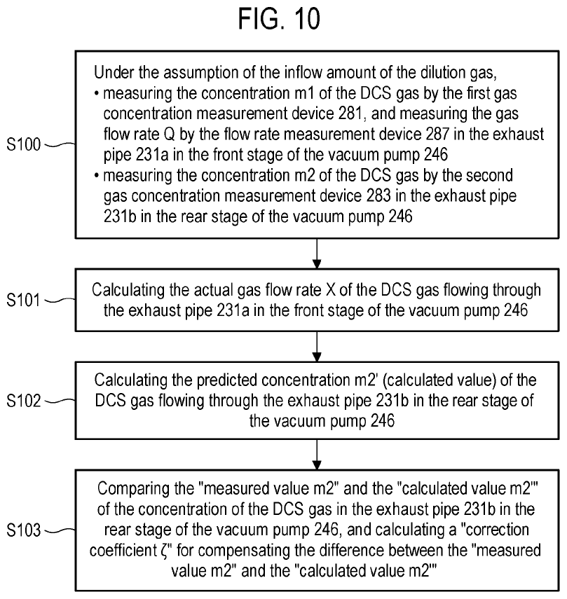

FIG. 10 is a diagram showing a flow at the time of initial value setting, which is suitably used in this modification of the embodiments of the present disclosure. As shown in FIG. 10, first, assuming the inflow amount of the dilution gas, the concentration m1 of the DCS gas in the exhaust pipe 231a at the front stage of the vacuum pump 246 is measured by the first gas concentration measurement device 281, and the gas flow rate Q is measured by the flow rate measurement device 287. Further, the concentration m2 of the DCS gas in the exhaust pipe 231b at the rear stage of the vacuum pump 246 is measured by the second gas concentration measurement device 283 (step S100).

Next, the flow rate X of the DCS gas in the exhaust pipe 231a at the front stage of the vacuum pump 246 is calculated (step S101).

Subsequently, the predicted concentration m2′ (calculated value) of the DCS gas in the exhaust pipe 231b at the rear stage of the vacuum pump 246 is calculated (step S102).

Then, the “measured value m2” and the “calculated value m2” of the concentration of the DCS gas in the exhaust pipe 231b at the rear stage of the vacuum pump 246 are compared, and a “correction coefficient ζ” for compensating a difference between the “measured value m2” and the “calculated value m2” is calculated (step S103).

The calculation of the initial setting data is performed as follows.

1) First, the dilution controller 290 controls the MFC 285 to set the inflow amount of the dilution gas to a (slm). Next, the concentration of the DCS gas in the exhaust pipe 231a at the front stage of the vacuum pump 246 is measured by the first gas concentration measurement device 281. Further, the flow rate of the gas in the exhaust pipe 231a at the front stage of the vacuum pump 246 is measured by the flow rate measurement device 287. Further, the concentration of the DCS gas in the exhaust pipe 231b at the rear stage of the vacuum pump 246 is measured by the second gas concentration measurement device 283 (step S100). The measurement results are as follows.

Concentration of DCS gas in exhaust pipe 231a (on primary side): m1(%)

Concentration of DCS gas in exhaust pipe 231b (on secondary side): m2(%)

Flow rate of gas in exhaust pipe 231a: Q (slm)

2) From the measurement results of 1) above, an actual gas flow rate X of the DCS gas flowing through the exhaust pipe 231a at the front stage of the vacuum pump 246 is calculated by the following Equation 7.

X=Q·(m1/100) (Equation 7)

This calculation is performed in step S101.

3) Next, assuming that the inflow amount of the dilution gas is a (slm), the predicted concentration m2′ (calculated value) of the DCS gas flowing through the exhaust pipe 231b at the rear stage of the vacuum pump 246 is calculated by the following Equation 8 (step S102).

X/(α+Q)=m2′/100

m2′=(100X)/(α+Q) (Equation 8)

In the above equation, the predicted concentration m2′ of the DCS gas can be calculated based on a volume flow ratio of the DCS gas to all gases.

4) Next, as for the concentration of the DCS gas flowing through the exhaust pipe 231b at the rear stage of the vacuum pump 246, the measured value m2 and the predicted concentration m2′ (calculated value) are compared, and the correction coefficient ζ is calculated. This correction coefficient ζ is used to infer the inflow amount α (slm) of the dilution gas used when calculating the concentration of the DCS gas in the exhaust pipe 231b at the rear stage of the vacuum pump 246 from the measured value of the concentration of the DCS gas in the exhaust pipe 231a at the front stage of the vacuum pump 246. The correction coefficient ζ is calculated by the following Equation 9.

ζ=m2/m2′ (Equation 9)

This calculation is performed in step S103.

### (Procedure During Operation)

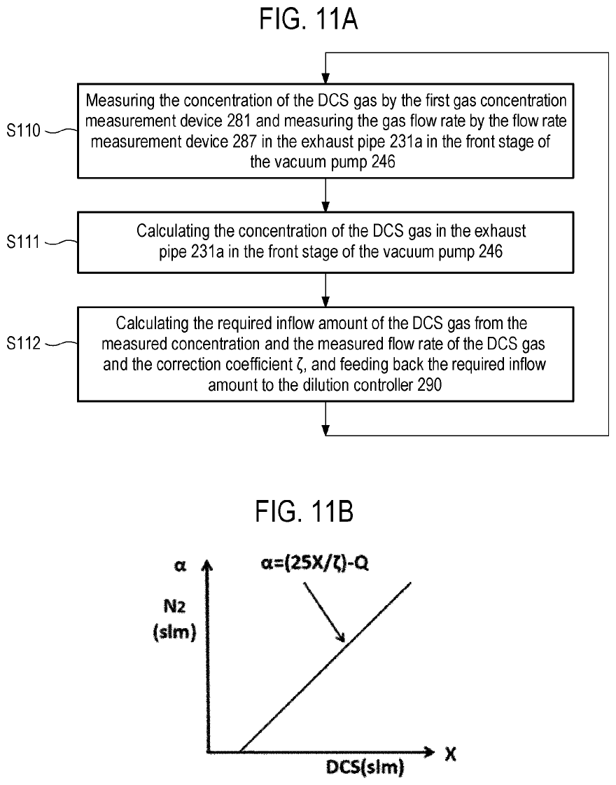

FIG. 11A is a diagram showing a control flow during operation of the dilution controller 290 suitably used in the modification of the present embodiment. FIG. 11B is a diagram illustrating a calculation example of the inflow amount of the dilution gas during operation of the dilution controller suitably used in the modification of the present embodiment.

First, the concentration of the DCS gas in the exhaust pipe 231a at the front stage of the vacuum pump 246 is measured by the first gas concentration measurement device 281. Further, the gas flow rate in the exhaust pipe 231a at the front stage of the vacuum pump 246 is measured by the flow rate measurement device 287 (step S110). The concentration of the DCS gas in the exhaust pipe 231a measured by the first gas concentration measurement device 281 and the gas flow rate measured by the flow rate measurement device 287 are sent to the dilution controller 290.

Next, the concentration of the DCS gas in the exhaust pipe 231a at the front stage of the vacuum pump 246 is calculated by the dilution controller 290 (step S111).

Then, the dilution controller 290 calculates the required inflow amount of the DCS gas based on the measured concentration and the measured flow rate of the DCS gas in step S110 and the correction coefficient obtained in step 103, and feeds-back the required inflow amount to the control of the MFC 285 by the dilution controller 290 (step S112). Accordingly, the dilution controller 290 controls the MFC 285 to allow the calculated inflow amount of the dilution gas to flow into the vacuum pump 246 (or the exhaust pipe 231a at the front stage of the vacuum pump 246).

By repeating the steps (S110, S111 and S112) described above, the substrate processing process is performed.

Calculation of the inflow amount of the dilution gas (N₂) during operation (at the time of performing the substrate processing process) can be performed as follows.

1) The concentration of the DCS gas in the exhaust pipe 231a at the front stage of the vacuum pump 246 is measured by the first gas concentration measurement device 281. Further, the gas flow rate in the exhaust pipe 231a at the front stage of the vacuum pump 246 is measured by the flow rate measurement device 287 (step S110). The measurement results are as follows.

Concentration of DCS gas in exhaust pipe 231a (on primary side): m1(%)

Gas flow rate in exhaust pipe 231a: Q (slm)

In a case where the flow rate measurement device 287 is a flow velocity measurement device, the flow rate can be calculated by giving a pipe inner diameter of the exhaust pipe 231a.

2) Based on the measurement results of 1) described above, the actual gas flow rate X of the DCS gas flowing through the exhaust pipe 231a at the front stage of the vacuum pump 246 is calculated by the following equation.

X=Q·(m1/100)

This calculation is performed in step S111.

3) In addition to the aforementioned Equations 1) and 2), the inflow amount α (slm) of the dilution gas is calculated by the following Equation 10 by using the correction coefficient ζ calculated in an initial setting.

X/(α+Q)=ζ(4/100) (Equation 10)

α=(25X/ζ)−Q (Equation 11)

In Equation 10, m2′=4(%) is substituted into a value of predicted concentration m2′ of Equation 8. By modifying Equation 10, it is possible to obtain Equation 11. Equation 11 is indicated in the graph of FIG. 11B. In the graph of FIG. 11B, the vertical axis represents the inflow amount a (slm) of the dilution gas (N₂), and the horizontal axis represents the flow rate X (slm) of the DCS gas.

The value of the inflow amount α (slm) of the dilution gas obtained by Equation 11 is fed-back to the dilution controller 290 (step S112). The dilution controller 290 controls the MFC 285 based on the inflow amount α (slm) of the dilution gas (N₂) obtained by Equation 11.

Accordingly, the dilution controller 290 can control the MFC 285 to supply the dilution gas into the vacuum pump 246 (or the exhaust pipe 231a at the front stage of the vacuum pump 246), and can control the supply amount of the inert gas so that the concentration of the DCS gas in the exhaust pipe 231b becomes 4.0% or less. This makes it possible to reliably suppress the combustion of the combustible gas (DCS gas) at the rear stage of the vacuum pump 246.

According to this modification, the same effects as those of the aforementioned embodiments may be obtained.

The embodiments of the present disclosure have been concretely described above. However, the present disclosure is not limited to the aforementioned embodiments, and various modifications may be made without departing from the spirit thereof.

For example, in the aforementioned embodiments, there has been described the examples where three electrodes are used as the plasma generation part. However, the present disclosure is not limited thereto. The present disclosure is also applicable to a case of using three or more odd number of electrodes such as five electrodes or seven electrodes. For example, in the case of forming a plasma generation part by using five electrodes, it may be possible to adopt a configuration in which three electrodes in total including two electrodes arranged at the outermost positions and one electrode arranged at the center position are connected to a high-frequency power source, and two electrodes arranged in such a form that the electrodes sandwiched by a high-frequency power source are grounded.

Further, in the aforementioned embodiments, there has been described the example where the number of electrodes on the high-frequency power source side is larger than the number of electrodes on the ground side, and the electrode on the ground side is made common to the electrodes on the high-frequency power source side. However, the present disclosure is not limited to the example. The number of electrodes on the ground side may be made larger than the number of electrodes on the high-frequency power source side, and the electrode on the high-frequency power source side may be made common to the electrodes on the ground side. However, when the number of electrodes on the ground side is made larger than the number of electrodes on the high-frequency power source side, the electric power applied to the electrodes on the high-frequency power source side may need to increase. Thus, many particles may be generated. Therefore, the number of electrodes on the high-frequency power source side may be set to be larger than the number of electrodes on the ground side.

Further, in the above-described embodiments, there has been described the example where the gas supply ports 302 and 304 formed in the buffer structure have the same opening area and are installed at the same opening pitch. However, the present disclosure is not limited to this example. The opening area of the supply ports 302 may be larger than the opening area of the gas supply ports 304. As the number of electrodes in the buffer chamber 237 increases, there is a high possibility that the plasma generated between the rod-shaped electrodes 269 and 270 located at the positions distant from the nozzle 249b becomes smaller than the plasma generated between the rod-shaped electrodes 270 and 271 located at the positions close to the nozzle 249b. Therefore, the opening area of the gas supply ports 302 formed at the positions distant from the nozzle 249b may be made larger than the opening area of the gas supply ports 304 formed at the positions close to the nozzle 249b.

Furthermore, in the above-described embodiments, there has been described the configuration in which, when installing a plurality of buffer structures, the same reaction gas is excited by plasma and supplied to the wafer. However, the present disclosure is not limited to this configuration. For each buffer structure, different reaction gases may be plasma-excited and supplied to the wafer. This makes it possible to control the plasma for each buffer chamber and to supply different reaction gases for each buffer chamber. As compared with a case where plural types of reaction gases are supplied by one buffer structure, some steps such as a purge step or the like may be reduced, thereby improving a throughput.

In the above-described embodiments, there has been described the example where the reaction gas is supplied after supplying the precursor. The present disclosure is not limited to such an example. The supply order of the precursor and the reaction gas may be reversed. That is, the precursor may be supplied after supplying the reaction gas. By changing the supply order, it becomes possible to change a film quality and a composition ratio of the film to be formed.

In the above-described embodiments, there has been described the example where the SiN film is formed on the wafer 200. The present disclosure is not limited to such an example and may also be suitably applied to a case where an Si-based oxide film such as a silicon oxide film (SiO film), a silicon oxycarbide film (SiOC film), a silicon oxycarbonitride film (SiOCN film), a silicon oxynitride film (SiON film) or the like is formed on the wafer 200, or a case where a Si-based nitride film such as a silicon carbonitride film (SiCN film), a silicon boronitride film (SiBN film), a silicon boron carbonitride film (SiBCN film) or the like is formed on the wafer 200. In these cases, as the reaction gas, in addition to the O-containing gas, it may be possible to use a C-containing gas such as C₃H₆ or the like, an N-containing gas such as NH₃ or the like, or a B-containing gas such as BCl₃ or the like.

The present disclosure may be suitably applied to a case where an oxide film or a nitride film containing a metal element such as titanium (Ti), zirconium (Zr), hafnium (Hf), tantalum (Ta), niobium (Nb), aluminum (Al), molybdenum (Mo), tungsten (W) or the like, that is, a metal-based oxide film or a metal-based nitride film is formed on the wafer 200. That is, the present disclosure may be suitably applied to a case where a TiO film, a TiN film, a TiOC film, a TiOCN film, a TiON film, a TiBN film, a TiBCN film, a ZrO film, a ZrN film, a ZrOC film, a ZrOCN film, a ZrON film, a ZrBN film, a ZrBCN film, a HfO film, a HfN film, a HfOC film, a HfOCN film, a HfON film, a HfBN film, a HfBCN film, a TaO film, a TaOC film, a TaOCN film, a TaON film, a TaBN film, a TaBCN film, an NbO film, an NbN film, an NbOC film, an NbOCN film, an NbON film, an NbBN film, an NbBCN film, an AlO film, an AN film, an AlOC film, an AlOCN film, an AlON film, an AlBN film, an AlBCN film, an MoO film, an MoN film, an MoOC film, an MoOCN film, an MoON film, an MoBN film, an MoBCN film, a WO film, a WN film, a WOC film, a WOCN film, a WON film, an MWBN film, a WBCN film or the like is formed on the wafer 200.

In these cases, as the precursor gas, it may be possible to use, for example, a tetrakis(dimethylamino) titanium (Ti[N(CH₃)₂]₄, abbreviation: TDMAT) gas, a tetrakis(ethylmethylamino) hafnium (Hf[N(C₂H₅) (CH₃)]₄, abbreviation: TEMAH) gas, a tetrakis(ethylmethylamino) zirconium (Zr[N(C₂H₅) (CH₃)]₄, abbreviation: TEMAZ) gas, a trimethylaluminum (Al(CH₃)₃, abbreviation: TMA) gas, a titanium tetrachloride (TiCl₄) gas, a hafnium tetrachloride (HfCl₄) gas or the like. As the reaction gas, it may be possible to use the aforementioned reaction gas.

That is, the present disclosure may be suitably applied to a case of forming a semimetal-based film containing a semimetal element or a metal-based film containing a metal element. The processing procedures and processing conditions of these film-forming processes may be the same as those of the film-forming process shown in the above-described embodiments and modifications. Even in these cases, effects similar to those of the above-described embodiments and modifications may be obtained.

The recipes used in the film-forming process may be individually provided according to the processing contents and stored in the memory device 121c via the electric communication line or the external memory device 123. When starting various processes, the CPU 121a may appropriately selects an appropriate recipe from the plurality of recipes stored in the memory device 121c according to the processing contents. This makes it possible to form thin films of various film types, composition ratios, film qualities and film thicknesses for general purposes and with high reproducibility in one substrate processing apparatus. It is also possible to reduce a burden on an operator and to quickly start various processes while avoiding operation errors.

The above-described recipes are not limited to the case of newly creating them, but may be provided by, for example, changing the existing recipes already installed in the substrate processing apparatus. In the case of changing the recipes, the changed recipes may be installed in the substrate processing apparatus via an electric communication line or a recording medium in which the recipes are recorded. In addition, by operating the input/output device 122 installed in the existing substrate processing apparatus, the existing recipes already installed in the substrate processing apparatus may be directly changed.

As described above, according to the present disclosure in some embodiments, it is possible to provide a technique capable of reliably suppressing combustion of a combustible gas at the rear stage of a vacuum pump.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a process chamber configured to process a substrate;
a gas supply system configured to supply a precursor gas into the process chamber;
an exhaust pipe connected to a vacuum pump and configured to evacuate an inside of the process chamber;
a gas concentration sensor configured to measure a concentration of the precursor gas passing through a first portion of the exhaust pipe that is at a front stage of the vacuum pump;
a pressure sensor configured to measure a pressure in a second portion of the exhaust pipe that is at a rear stage of the vacuum pump;
a dilution gas supply system configured to supply a dilution gas into the vacuum pump or the first portion of the exhaust pipe that is at the front stage of the vacuum pump; and
a controller configured to be capable of controlling the dilution gas supply system to supply the dilution gas into the vacuum pump or the first portion of the exhaust pipe at the front stage of the vacuum pump at a flow rate corresponding to the measured concentration of the precursor gas and the measured pressure in the second portion of the exhaust pipe at the rear stage of the vacuum pump.

2. The substrate processing apparatus of claim 1, wherein the gas concentration sensor configured to measure the concentration of the precursor gas passing through the first portion of the exhaust pipe at the front stage of the vacuum pump is used as a first gas concentration sensor,
wherein the substrate processing apparatus further comprises:
a second gas concentration sensor configured to measure a concentration of the precursor gas in the second portion of the exhaust pipe at the rear stage of the vacuum pump; and
wherein the controller is further configured to be capable of preliminarily acquire and store into a memory a correlation among a concentration of the precursor gas in the first portion of the exhaust pipe at the front stage of the vacuum pump, which is measured by the first gas concentration sensor, the concentration of the precursor gas in the second portion of the exhaust pipe at the rear stage of the vacuum pump, which is measured by the second gas concentration sensor, with respect to the flow rate of the dilution gas supplied into the vacuum pump and a pressure in the second portion of the exhaust pipe at the rear stage of the vacuum pump, which is measured by the pressure sensor, and
wherein when exhausting the precursor gas, the controller is further configured to be capable of measuring the concentration of the precursor gas with the first gas concentration sensor, measuring the pressure in the second portion of the exhaust pipe at the rear stage of the vacuum pump with the pressure sensor, and controlling the dilution gas supply system to supply the dilution gas into the vacuum pump or the first portion of the exhaust pipe at the front stage of the vacuum pump at a flow rate corresponding to the concentration of the precursor gas measured by the first gas concentration sensor and the pressure measured by the pressure sensor, based on the correlation stored in the memory.

3. The substrate processing apparatus of claim 1, wherein the precursor gas is a DCS gas, and
wherein the controller is further configured to be capable of controlling the dilution gas supply system to supply the dilution gas into the vacuum pump or the first portion of the exhaust pipe at the front stage of the vacuum pump such that the concentration of the DCS gas in the second portion of the exhaust pipe at the rear stage of the vacuum pump becomes 4.0% or less.

4. A method of manufacturing a semiconductor device, comprising:
loading a substrate into a process chamber of a substrate processing apparatus that includes the process chamber configured to process the substrate, a gas supply system configured to supply a precursor gas into the process chamber, an exhaust pipe connected to a vacuum pump and configured to evacuate an inside of the process chamber, a gas concentration sensor configured to measure a concentration of the precursor gas passing through a first portion of the exhaust pipe at a front stage of the vacuum pump, a pressure sensor configured to measure a pressure in a second portion of the exhaust pipe at a rear stage of the vacuum pump, and a dilution gas supply system configured to supply a dilution gas into the vacuum pump or the first portion of the exhaust pipe at the front stage of the vacuum pump;
supplying the precursor gas to the substrate in the process chamber from the gas supply system; and
exhausting the precursor gas in the process chamber while supplying the dilution gas into the vacuum pump or the first portion of the exhaust pipe at the front stage of the vacuum pump at a flow rate corresponding to the concentration of the precursor gas, which is measured by the gas concentration sensor, and the pressure in the second portion of the exhaust pipe at the rear stage of the vacuum pump, which is measured by the pressure sensor.

5. The method of claim 4, wherein the gas concentration sensor configured to measure the concentration of the precursor gas passing through the first portion of the exhaust pipe at the front stage of the vacuum pump is used as a first gas concentration sensor,
wherein the substrate processing apparatus further includes a second gas concentration sensor configured to measure a concentration of the precursor gas in the second portion of the exhaust pipe at the rear stage of the vacuum pump,
wherein the method further comprises: preliminarily acquiring and storing a correlation among a concentration of the precursor gas in the first portion of the exhaust pipe at the front stage of the vacuum pump, which is measured by the first gas concentration sensor, a concentration of the precursor gas in the second portion of the exhaust pipe at the rear stage of the vacuum pump, which is measured by the second gas concentration sensor, with respect to the flow rate of the dilution gas supplied into the vacuum pump and a pressure in the second portion of the exhaust pipe at the rear stage of the vacuum pump, which is measured by the pressure sensor, and
wherein in the act of exhausting the precursor gas, the concentration of the precursor gas is measured with the first gas concentration sensor, the pressure in the second portion of the exhaust pipe at the rear stage of the vacuum pump is measured with the pressure sensor, and the dilution gas is supplied into the vacuum pump or the first portion of the exhaust pipe at the front stage of the vacuum pump at a flow rate corresponding to the concentration of the precursor gas measured by the first gas concentration sensor and the pressure measured by the pressure sensor, based on the stored correlation.

6. The method of claim 4, wherein the precursor gas is a DCS gas, and
wherein in the act of exhausting the precursor gas, the dilution gas is supplied into the vacuum pump or the first portion of the exhaust pipe at the front stage of the vacuum pump such that the concentration of the DCS gas in the second portion of the exhaust pipe at the rear stage of the vacuum pump becomes 4.0% or less.

7. A non-transitory computer-readable recording medium storing a program that causes, by a computer, a substrate processing apparatus to perform a process comprising:
loading a substrate into a process chamber of the substrate processing apparatus that includes the process chamber configured to process the substrate, a gas supply system configured to supply a precursor gas into the process chamber, an exhaust pipe connected to a vacuum pump and configured to evacuate an inside of the process chamber, a gas concentration sensor configured to measure a concentration of the precursor gas passing through a first portion of the exhaust pipe at a front stage of the vacuum pump, a pressure sensor configured to measure a pressure in a second portion of the exhaust pipe at a rear stage of the vacuum pump, and a dilution gas supply system configured to supply a dilution gas into the vacuum pump or the first portion of the exhaust pipe at the front stage of the vacuum pump;
supplying the precursor gas to the substrate in the process chamber from the gas supply system; and
exhausting the precursor gas while supplying the dilution gas into the vacuum pump or the first portion of the exhaust pipe at the front stage of the vacuum pump at a flow rate corresponding to the concentration of the precursor gas, which is measured by the gas concentration sensor, and the pressure in the second portion of the exhaust pipe at the rear stage of the vacuum pump, which is measured by the pressure sensor.

8. The non-transitory computer-readable recording medium of claim 7, wherein the gas concentration sensor configured to measure the concentration of the precursor gas passing through the first portion of the exhaust pipe at the front stage of the vacuum pump is used as a first gas concentration sensor,
wherein the substrate processing apparatus further includes a second gas concentration sensor configured to measure a concentration of the precursor gas in the second portion of the exhaust pipe at the rear stage of the vacuum pump,
wherein the process further comprises: preliminarily acquiring and storing a correlation among a concentration of the precursor gas in the first portion of the exhaust pipe at the front stage of the vacuum pump, which is measured by the first gas concentration sensor, a concentration of the precursor gas in the second portion of the exhaust pipe at the rear stage of the vacuum pump, which is measured by the second gas concentration sensor, with respect to the flow rate of the dilution gas supplied into the vacuum pump and a pressure in the second portion of the exhaust pipe at the rear stage of the vacuum pump, which is measured by the pressure sensor, and
wherein in the act of exhausting the precursor gas, the concentration of the precursor gas is measured with the first gas concentration sensor, the pressure in the second portion of the exhaust pipe at the rear stage of the vacuum pump is measured with the pressure sensor, and the dilution gas is supplied into the vacuum pump or the first portion of the exhaust pipe at the front stage of the vacuum pump at a flow rate corresponding to the concentration of the precursor gas measured by the first gas concentration sensor and the pressure measured by the pressure sensor, based on the stored correlation.

9. The non-transitory computer-readable recording medium of claim 7, wherein the precursor gas is a DCS gas, and
wherein in the act of exhausting the precursor gas, the dilution gas is supplied into the vacuum pump or the first portion of the exhaust pipe at the front stage of the vacuum pump such that the concentration of the DCS gas in the second portion of the exhaust pipe at the rear stage of the vacuum pump becomes 4.0% or less.
